(19) United States
(12) Patent Application Publication
(10) Pub. No.: US 2021/0383948 A1
(43) Pub. Date: Dec. 9, 2021

(54) SIGNAL TRANSMISSION FLAT CABLE AND METHOD FOR MANUFACTURING SAME

(71) Applicant: TERAOKA SEISAKUSHO CO., LTD., Tokyo (JP)

(72) Inventor: Kazuhiro YOKOKURA, Tokyo (JP)

(73) Assignee: TERAOKA SEISAKUSHO CO., LTD., Tokyo (JP)

(21) Appl. No.: 17/252,436

(22) PCT Filed: Jul. 26, 2019
(86) PCT No.: PCT/JP2019/029425

§ 371 Date: Aug. 11, 2021

(30) Foreign Application Priority Data
Jul. 27, 2018 (JP) 2018-141348

(51) Int. Cl. H01B 7/08; H01B 7/18; H01B 13/06; H01B 13/22; H01B 11/00

(52) U.S. Cl. CPC H01B 7/08; H01B 7/18; H01B 11/00; H01B 13/22; H01B 13/06

(57) ABSTRACT

The flat cable 10 has at one end or both ends a connector section 11 on which a connector conductor 15 electrically connectable to a ground layer of an electronic circuit board is formed. Signal conductors 12, 13 are covered by a protective shield layer 20 having a metal layer on the inside and an insulating plastic layer on the outside. The metal layer of the protective shield layer is electrically connected to the connector conductor 15 of the connector section, and a portion 17a of the metal layer of the protective shield layer is exposed to the outside of the protective shield layer 20 and functions as a ground layer.

### TECHNICAL FIELD

The present invention relates to a signal transmission flat cable that is thin and has exceptional electrical characteristics, and in particular relates to a signal transmission flat cable and a method for manufacturing the same that is suitable for internal wiring of cellular telephones, notebook computers, and the like.

### BACKGROUND ART

In signal transmission flat cables that are used for electronic devices with high density wiring such as cellular telephones and notebook computers, it is necessary that they are thin in order to enable wiring in a narrow space and have low loss of transmission in high-frequency bandwidths.

As such a signal transmission flat cable, a coaxial cable has been proposed in which an electrically insulating substrate on which signal conductors are layered is covered with electrically insulating thin film layers from above and below, and are surrounded by a protective shield layer with a metal layer on the inside and an electrically insulating plastic layer on the outside to provide an electrical connection with a ground via the metal layer (Patent Document 1).

It is also known to extend an outer conductor surrounding a shielded cable to function as a ground layer in a high frequency circuit (Patent Document 2).

### PRIOR ART DOCUMENTS

### Patent Documents

Patent Document 1: WO2016/104066

Patent Document 2: JP 2014-011047 A

### SUMMARY OF INVENTION

### Problems to be Solved

However, in the configurations described in Patent Documents 1 and 2, the cable is not provided with a connector section connected to the electronic circuit board and has no ground connection at the connector section, so that noise cannot be sufficiently removed. This caused a problem that the S/N ratio was lowered.

It is therefore an object of the present invention to solve such problems and provide a signal transmission flat cable being capable of reliably removing noise for improvement in S/N ratio and a method for manufacturing the same.

### Means for Solving the Problems

The present invention (claim 1) for solving the above-mentioned problems relates to a signal transmission flat cable having at one or both ends a connector section on which a connector conductor electrically connectable to a ground layer of an electronic circuit board is formed, comprising:

one or a plurality of signal conductors made of a metal thin film that extends in the cable-length direction;

an upper insulating thin film layer and a lower insulating thin film layer that cover the signal conductor from above and below in the cable-thickness direction; and

a protective shield layer that comprises a metal layer and an insulating plastic layer and surrounds the outer peripheries of the upper and lower electrically insulating thin film layers such that the metal layer is disposed inside and the insulating plastic layer outside;

wherein the metal layer of the protective shield layer is electrically connected to the connector conductor of the connector section.

The present invention (claim 3) also relates to a signal transmission flat cable having at one or both ends a connector section on which a connector conductor electrically connectable to a ground layer of an electronic circuit board is formed, comprising:

one or a plurality of signal conductors made of a metal thin film that extends in the cable-length direction;

an upper insulating thin film layer and a lower insulating thin film layer that cover the signal conductor from above and below in the cable-thickness direction; and

a protective shield layer that comprises a metal layer and an insulating plastic layer and surrounds the outer peripheries of the upper and lower electrically insulating thin film layers such that the metal layer is disposed inside and the insulating plastic layer outside;

wherein a portion of the metal layer of the protective shield layer is exposed to the outside of the insulating plastic layer.

The present invention (claim 7) also relates to a method for manufacturing a signal transmission flat cable having at one or both ends a connector section on which a connector conductor electrically connectable to a ground layer of an electronic circuit board is formed, comprising:

etching a lower insulating thin film layer made of an insulating liquid crystal polymer film laminated with copper foil such that a portion to be the signal conductor remains, thereby forming the signal conductor on the lower insulating thin film layer;

laminating an upper insulating thin film layer on the signal conductor;

disposing a protective shield layer comprising a metal layer and an insulating plastic layer such that the metal layer turns inside and the insulating plastic layer outside, and surrounding the outer peripheries of the upper and lower electrically insulating thin film layers with the protective shielding layer such that a portion of the metal layer of the protective shield layer is exposed to the outside of the insulating plastic layer; and

applying heat and pressure to the protective shield layer to integrate the lower insulating thin film layer, the upper insulating thin film layer and the protective shield layer.

### Effect of the Invention

In the present invention, the signal transmission flat cable can have a ground function at the connector section provided at the end thereof or at the outside of the flat cable, so that noise can be reliably removed, allowing the S/N ratio to be improved.

### BRIEF DESCRIPTION OF DRAWINGS

FIG. 1a is a plan view showing a signal transmission flat cable according to the present invention;

FIG. 1b is an enlarged view showing a connector section of the signal transmission flat cable;

FIG. 1c is a plan view showing, in a developed state, a protective shield layer at the connector section of the signal transmission flat cable;

FIG. 2a is a cross-sectional view along the line A-A′ in FIG. 1a;

FIG. 2b is a cross-sectional view along the line B-B′ in FIG. 1a;

FIG. 3a is a cross-sectional view along the line C-C′ in FIG. 1b;

FIG. 3b is a cross-sectional view along the line D-D′ in FIG. 1b;

FIG. 4 is an illustrative view showing steps of manufacturing the signal transmission flat cable;

FIG. 5 is a plan view showing the surface of a metal layer of the protective shield layer;

FIG. 6 is a perspective view showing a state in which the protective shield layer is bent; and

FIG. 7 is an illustrative view showing the signal transmission flat cable that is arranged in an electronic device.

### MODE OF CARRYING OUT THE INVENTION

The present invention will be described in detail blow based on the embodiments shown in the drawings.

### Embodiment

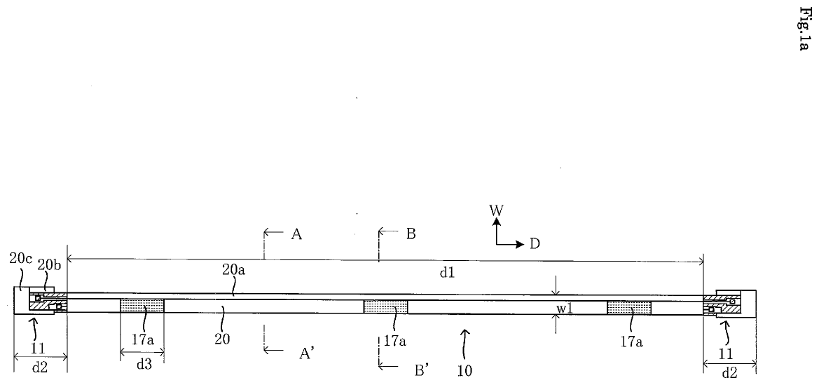

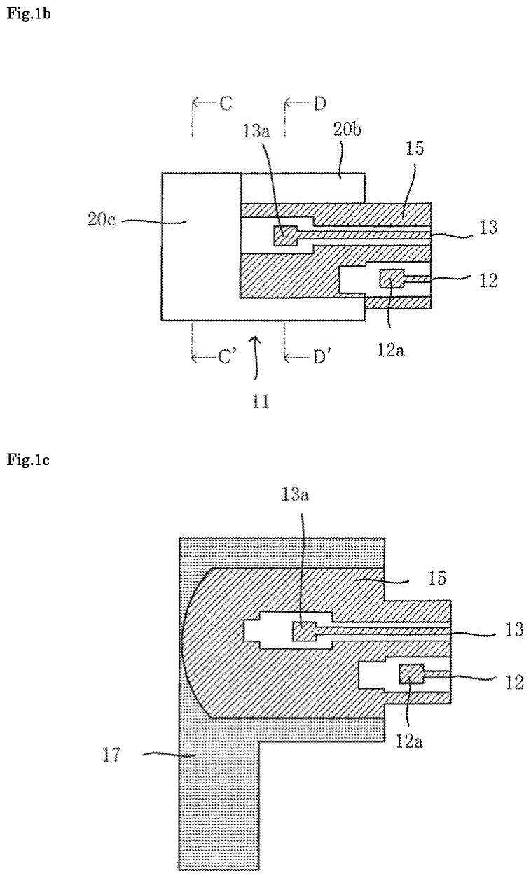

FIG. 1a shows a signal transmission flat cable (hereinafter referred to as a flat cable) 10 according to the present embodiment. As shown in FIGS. 1b and 1c, the flat cable 10 has at both ends connector sections 11 of the same configuration that are connected to electronic circuit boards.

As will be described later, the flat cable 10 is surrounded at the outer surface by a protective shield layer 20 having a metal layer on the inside and an insulating plastic layer on the outside in such a manner that one end 20a in the cable-width direction is overlapped with the other end. A portion 17a of the metal layer of the protective shield layer 20 is exposed to the outer surface of the flat cable 10 at a plurality of locations (three locations) in the cable-length direction. These exposed metal layers 17a serve as a ground layer as described later, and the flat cable 10 thus provides a multi-point ground structure.

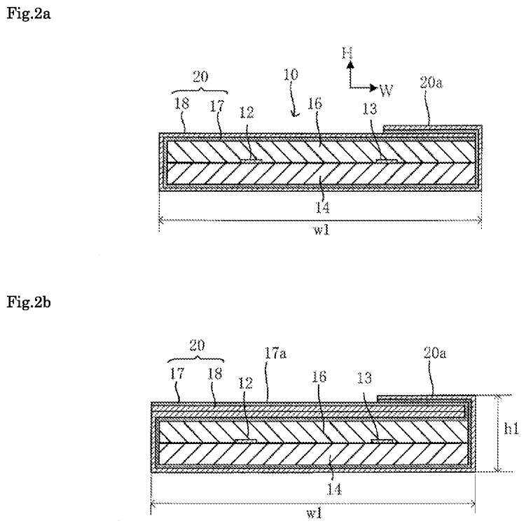

In the present specification, the cable-length direction is the direction indicated by D in FIG. 1a in which the flat cable 10 extends, the cable-width direction is the direction indicated by W orthogonal to D, and the cable-thickness direction is the direction indicated by H in FIG. 2a which is orthogonal to D and W.

The flat cable 10 is configured as a multi-core coaxial cable, and two signal conductors 12 and 13 are, as shown in FIGS. 2a and 2b, arranged on a plane parallel to each other in the cable-length direction. The signal conductors 12 and 13 are formed by using a lower insulating thin film layer 14 made of an insulating liquid crystal polymer film having a thickness of 87μ on which a metal having good conductivity, for example, copper foil is laminated, and etching it such that portions to be the signal conductors remain. In the present embodiment, the two signal conductors 12 and 13 are provided, but the number of signal conductors is not limited to two, and more signal conductors (multi-core) can be provided. It is also possible to use one (single core).

The signal conductors 12 and 13 extend into the inside of the connector section 11, as shown in FIGS. 1b and 1c, and the terminals 12a and 13a thereof are guided into the voids of a connector conductor 15. Similar to the signal conductors 12 and 13, the connector conductor 15 is formed by etching the lower insulating thin film layer 14 such that a portion to be the connector conductor 15 remains.

As shown in FIG. 1b, also at the connector section 11, the protective shield layer 20 is at one end 20b overlapped on the connector conductor 15 in the cable-width direction and at the other end 20c entirely overlapped thereon in the cable-width direction such that part of the connector conductor 15 and the terminals 12a and 13a of the signal conductors are exposed to the outer surface of the flat cable 10. FIG. 1c is a development view of the protective shield layer 20 at the connector section 11. The back side of the protective shield layer 20 is a metal layer 17. When the end portions 20b and 20c of the protective shield layer 20 are, as shown in FIG. 1b, overlapped, the metal layer 17 of the protective shield layer 20 is electrically connected to the connector conductor 15.

The signal conductors 12 and 13 formed on the lower insulating thin film layer 14 are covered except for the connector section 11 with an upper insulating thin film layer 16 made of an insulating liquid crystal polymer film having a thickness of 75μ, for example. The signal conductors 12 and 13 may be formed on one surface (upper side surface) of an electrically insulating substrate (not shown) as shown in Patent Document 1, and the electrically insulating substrate may be covered with insulating thin film layers made of a liquid crystal polymer film from above and below. In any case, the signal conductors 12 and 13 are covered with the insulating thin film layers from above and below.

The lower and upper insulating thin film layers 14 and 16 that cover the signal conductors 12 and 13 from above and below are entirely covered with the protective shield layer 20 composed of a metal layer 17 made of a copper foil having a thickness of 6μ, for example, and an insulating plastic layer 18 of polyimide having a thickness of 12μ, for example, such that the insulating plastic layer 18 comes on the outside.

The flat cable 10 has a length d1 (for example, about 84.0 mm) in the cable-length direction at the portion excluding the connector section, a length d2 (for example, about 7.0 mm) at the connector section 11, and a length d3 (for example, about 5.8 mm) at the metal layer 17a that functions as a ground layer. The flat cable has a width w1 (for example, about 2.6 mm) in the cable-width direction and a thickness hl (for example, about 0.2 mm) in the cable-thickness direction (FIG. 2b). Since FIGS. 2a, 2b, 3a, 3b and 4 are schematic illustrative views, the dimensional ratio of each portion is different from the actual size, and in particular, the dimension in the cable-thickness direction is illustrated in a greatly exaggerated size.

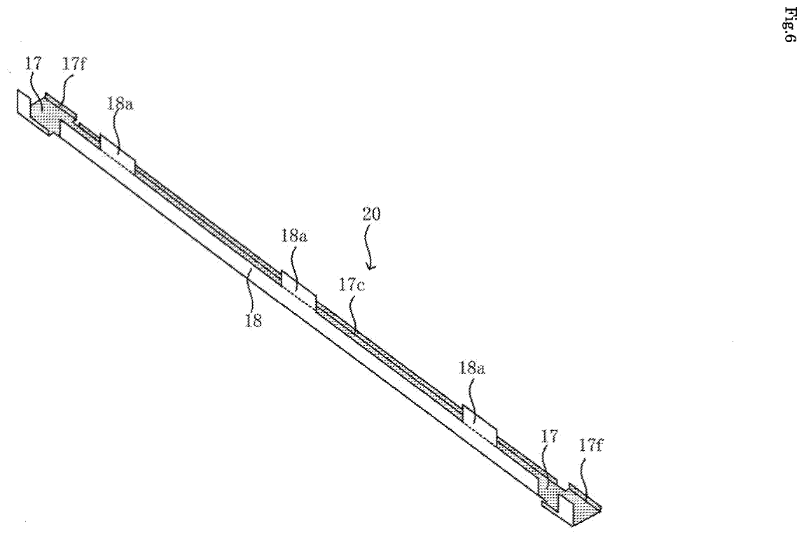

FIG. 5 shows the protective shield layer 20 that is developed so that the metal layer 17 appears on the paper plane. The protective shield layer 20 is partly elongated in the cable-width direction at a plurality of portions in the cable-length direction, and the elongated portion of the metal layer 17a is exposed as a ground layer on the outer surface of the flat cable 10, as shown in FIG. 1a.

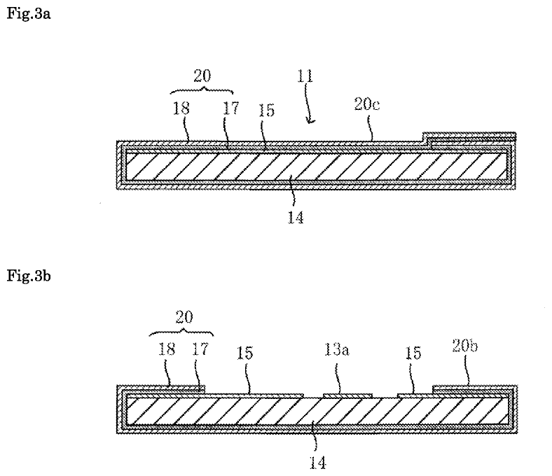

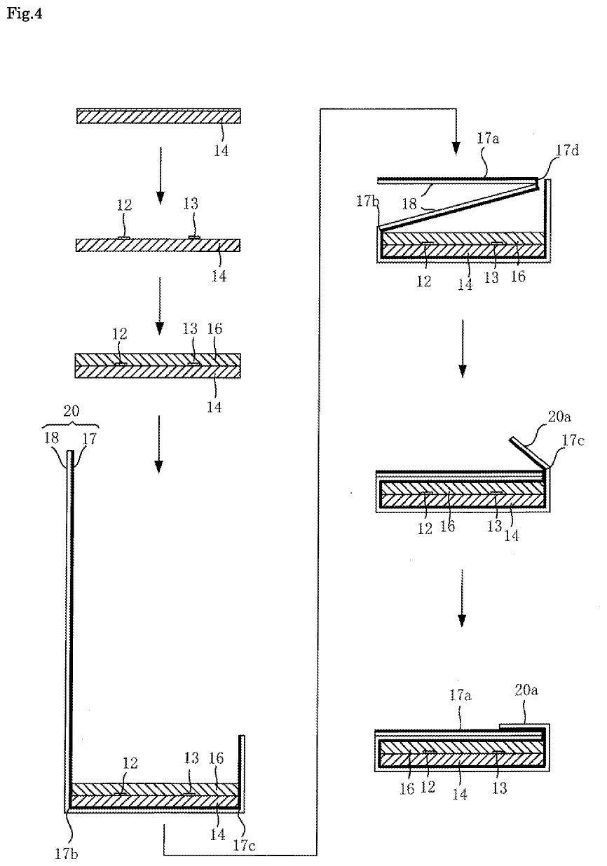

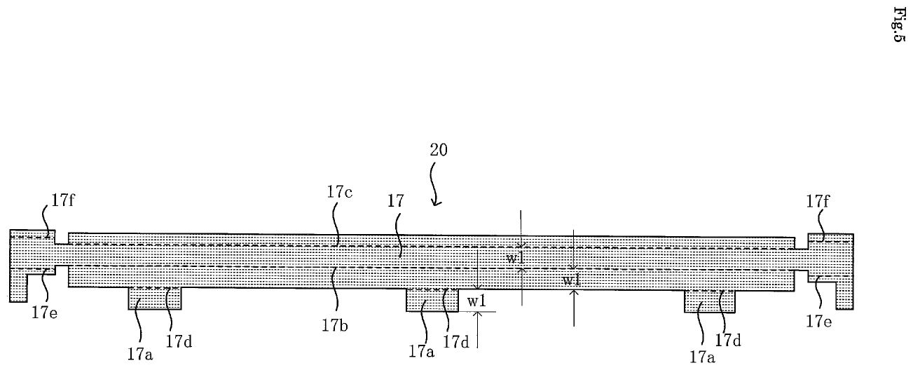

Since the protective shield layer 20 is bent to surround the flat cable 10, the bent portion is shown by the dotted line in FIG. 5 using the reference numerals 17b to 17f. The bent portions 17b to 17f actually have a width corresponding to the thickness hl in the cable-thickness direction, but since it is difficult to illustrate, they are shown as one dotted line. Further, in FIGS. 2a, 2b, 3a, and 3b, the cable-thickness direction is exaggeratedly shown in a large size, and therefore, it is not shown to which portion the bent portion corresponds.

The width between the bent portions 17b and 17c of the protective shield layer 20, the width between the bent portions 17b and 17d, and the width between the bent portion 17d and the distal end of the metal layer 17a correspond to the width w1 of the flat cable 10 in the cable-width direction. The protective shield layer 20 is bent at a right angle inward along the bent portions 17b and 17c. The protective shield layer 20 is also bent at the connector section inward along the bent portions 17e and 17f. The protective shield layer 20 thus bent is illustrated in FIG. 6 as a perspective view. In FIG. 6, the insulating plastic layer 18 of the protective shield layer 20 is visible, and a portion corresponding to the portion of the metal layer 17a is shown by reference numeral 18a.

The protective shield layer 20 is folded in the state as shown in FIG. 6 along the bent portion 17b on the upper insulating thin film layer 16 (not shown in FIG. 6) inside the protective shield layer 20, and folded at the portion of the metal layer 17a in the opposite direction along the bent portion 17d such that the portion of the metal layer 17a is exposed to the insulating plastic layer 18. As described later, the exposed metal layer 17a can be electrically connected to the ground layer of an electronic circuit board directly or through a metal fitting such as a clip. In this state, the protective shield layer 20 is bent at one end 20a along the bent portion 17c and overlapped on the other end thereof. In the state where the whole is covered by the protective shield layer 20, a portion where the portion of the metal layer 17a is not exposed is shown in cross-section in FIG. 2a, and a portion where the portion of the metal layer 17a is exposed is shown in cross-section in FIG. 2b.

Since the upper insulating thin film layer 16 is not provided at the connector section 11, the protective shield layer 20 is bent at one end 20b in the cable-width direction on the connector conductor 15 along the bent portion 17f, and bent at the terminal end 20c along the bent portion 17e. In the state covered by the protective shield layer 20, a cross-sectional view along the line C-C′ in FIG. 1b is shown in FIG. 3a, and a cross-sectional view along the line D-D in FIG. 1b is shown in FIG. 3b. As is clear from these figures, the connector conductor 15 is in contact with the metal layer 17 of the protective shield layer 20 for electrical connection.

In the flat cable 10 covered with the protective shield layer 20, heat and pressure (hot press) is applied to the protective shield layer 20 from above and below to soft and melt the lower insulating thin film layer 14 and the upper insulating thin film layer 16 for adhesion to the metal layer 17, thus integrating the lower insulating thin film layer 14, the upper insulating thin film layer 16 and the protective shield layer 20.

Next, a method for manufacturing the flat cable 10 will be described with reference to FIG. 4 which is a sectional view of a portion where the exposed metal layer 17a is formed.

As shown on the left side of FIG. 4, the lower insulating thin film layer 14 made of an insulating liquid crystal polymer film laminated with a copper foil is etched so that the portions to be the signal conductors 12 and 13 remain, thereby forming the signal conductors 12 and 13 on the lower insulating thin film layer 14.

Subsequently, the upper insulating thin film layer 16 is laminated on the signal conductors 12 and 13, and the upper insulating thin film layer 16 and the lower insulating thin film layer 14 are disposed between the bent portions 17b and 17c of the metal layer 17 of the protective shield layer 20. As shown in the lower left of FIG. 4, the protective shield layer 20 is vertically bent at the bent portions 17b and 17c to turn the metal layer 17 inside and the insulating plastic layer 18 outside. Since the thickness of the flat cable is exaggeratedly shown in FIG. 4 as well, the bent portions shown in FIG. 4 don't indicate an accurate position.

As shown on the right side of FIG. 4, the protective shield layer 20 is bent inward along the bent portion 17b, and then bent back in the opposite direction along the bent portion 17d so that the metal layer 17a appears on the insulating plastic layer 18. In this state, as shown in the lower right of FIG. 4, the protective shield layer 20 is bent at one end 20a along the bent portion 17c and overlapped on the other end thereof, as shown in the lower right of FIG. 4.

On the other hand, at the connector section 11, although not shown, the protective shield layer 20 is bent at one end 20b in the cable-width direction on the connector conductor 15 along the bent portion 17f, and then bent at the terminal end 20c along the bent portion 17e.

Subsequently, the protective shield layer 20 is heated and pressed from above and below to integrate the lower insulating thin film layer 14, the upper insulating thin film layer 16 and the protective shield layer 20 to produce the flat cable 10.

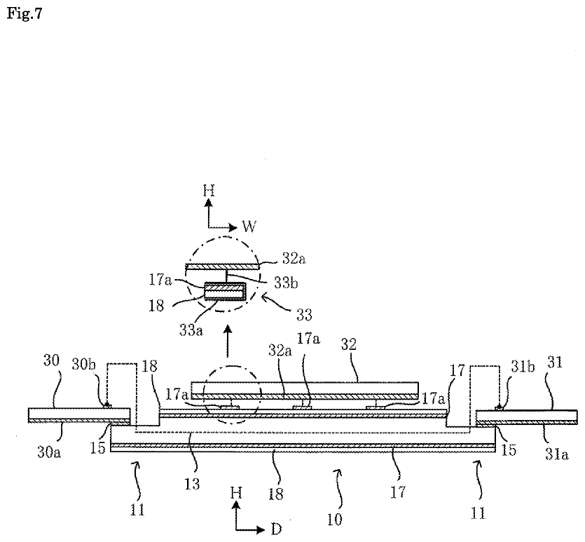

FIG. 7 schematically illustrates an example in which the flat cable 10 is applied to an electronic device such as a smartphone, for example. FIG. 7 is a functional diagram in which the flat cables 10 is shown enlarged in the cable-thickness direction H to illustrate how the metal layers 17, 17a are electrically connected.

The connector section 11 at one end of the flat cable 10 is inserted into an electronic circuit board 30 so that the connector conductor 15 of the connector section 11 is electrically connected to a ground layer 30a of the electronic circuit board 30. On the other hand, the connector section 11 at the other end of the flat cable 10 is inserted into an electronic circuit board 31 so that the connector conductor 15 of the connector section 11 is electrically connected to a ground layer 31a of the electronic circuit board 31.

The signal conductor 13 is connected via the terminal 13a (FIGS. 1b and 1c) thereof to a terminal 30b of the electronic circuit board 30 that is connected to, for example, an antenna element (not shown). The other terminal 13a of the signal conductor 13 is connected to a terminal 31b of the electronic circuit board 31 that is connected to a high frequency circuit (not shown). The signal received by the antenna element is received and processed via the signal conductor 13 by the high frequency circuit of the electronic circuit board 31.

Here, the connector conductor 15 is electrically connected to the metal layer 17 of the protective shield layer 20, as shown in FIGS. 3a and 3b. The connector conductor 15 is also electrically connected to the ground layers 30a and 31a of the electronic circuit boards 30, 31. The signal conductors 12 and 13 are surrounded by the metal layer 17 that electrically functions as a ground layer over the entire area in the cable-length direction. Therefore, noise during signal transmission can be remarkably suppressed, and the S/N ratio can be improved.

As shown in FIG. 7, the flat cable 10 is also disposed close to a ground layer 32a of another electronic circuit board 32, and the metal layer 17a exposed to the outer surface of the flat cable can be electrically connected to the ground layer 32a of the electronic circuit board 32. This electrical connection is performed using, for example, a clip-shaped metal fitting 33, as shown in the upper part of the virtual circle. The metal fitting 33 has a metal flame 33a having a size of w1 in the cable-width direction W and hl in the thickness direction H with a pin 33b provided on one side thereof. The flat cable is clipped so that the metal layer 17a is electrically connected to the metal frame 33a, and the pin 33b is brought into contact with or punctured the ground layer 32a of the electronic circuit board 32 to electrically connect the metal layer part 17a to the ground layer 32a. The metal layer 17 surrounding the flat cable 10 is electrically connected to the ground layer 32a of the electronic circuit board 32 via the metal layer 17a, so that the signal conductors 12 and 13 are surrounded by the metal layer 17 that electrically functions as a ground layer over the entire area in the cable-length direction. Therefore, noise during signal transmission can be remarkably suppressed, and the S/N ratio can be improved.

The metal layer 17a is electrically connected to the ground layer 32a of the electronic circuit board 32 via the metal fitting 33. However, the electrical connection may be made by, if possible, bringing the flat cable 10 into contact with the ground layer 32a.

In the present embodiment, the connector section is provided at both ends of the flat cable 10. However, the connector section may be provided only at one end. In this case, the other terminal of the signal conductor is directly connected to a connection terminal of the electronic circuit board without using a connector.

The flat cable of the present embodiment has been described as being mainly used in high-density wiring electronic devices such as smartphones. However, the present invention is not limited to that, and can also be applied to, for example, a wire harness in which a plurality of signal conductor wires are bundled that are used for power supply and signal communication for automobiles and other electronic devices.

### KEY TO THE SYMBOLS

10 flat cable
11 connector section
12, 13 signal conductor
14 lower insulating thin film layer
15 connector conductor
16 upper insulating thin film layer
17, 17a metal layer
18 insulating plastic layer
20 protective shield layer
30, 31, 32 electronic circuit board
33 metal fitting

1. (canceled)

2. (canceled)

3. A signal transmission flat cable having at one or both ends a connector section on which a connector conductor electrically connectable to a ground layer of an electronic circuit board is formed, comprising:
one or a plurality of signal conductors made of a metal thin film that extends in the cable-length direction;
an upper insulating thin film layer and a lower insulating thin film layer that cover the signal conductor from above and below in the cable-thickness direction; and
a protective shield layer that comprises a metal layer and an insulating plastic layer and surrounds the outer peripheries of the upper and lower electrically insulating thin film layers such that the metal layer is disposed inside and the insulating plastic layer outside;
wherein a portion of the metal layer of the protective shield layer is exposed to the outside of the insulating plastic layer
wherein the protective shield layer is overlapped at one end edge in the cable-length direction with the outside of the other end edge to surround the outer peripheries, and the portion of the metal layer of the protective shield layer is exposed to the outside of the insulating plastic layer in the cable-width direction from the overlapped portion of the protective shield layer to a portion that is not overlapped.

4. A signal transmission flat cable according to claim 3, wherein the portion of the metal layer of the protective shield layer is electrically connected to the ground layer of the electronic circuit board directly or through the metal fitting.

5. A signal transmission flat cable according to claim 3, wherein the portion of the metal layer of the protective shield layer is exposed to the outside of the insulating plastic layer at a plurality of locations in the cable-length direction.

6. A signal transmission flat cable according to claim 3, wherein the metal layer of the protective shield layer is electrically connected to the connector conductor of the connector section.

7. A method for manufacturing a signal transmission flat cable having at one or both ends a connector section on which a connector conductor electrically connectable to a ground layer of an electronic circuit board is formed, comprising:
etching a lower insulating thin film layer made of an insulating liquid crystal polymer film laminated with copper foil such that a portion to be the signal conductor remains, thereby forming the signal conductor on the lower insulating thin film layer;
laminating an upper insulating thin film layer on the signal conductor;
disposing a protective shield layer comprising a metal layer and an insulating plastic layer such that the metal layer turns inside and the insulating plastic layer outside, and surrounding the outer peripheries of the upper and lower electrically insulating thin film layers with the protective shielding layer such that a portion of the metal layer of the protective shield layer is exposed to the outside of the insulating plastic layer such that the protective shield layer is overlapped at one end edge in the cable-length direction with the outside of the other end edge and the portion of the metal layer of the protective shield layer is exposed to the outside of the insulating plastic layer in the cable-width direction from the overlapped portion of the protective shield layer to a portion that is not overlapped; and
applying heat and pressure to the protective shield layer to integrate the lower insulating thin film layer, the upper insulating thin film layer and the protective shield layer.
